(19) United States
(12) Patent Application Publication
(10) Pub. No.: US 2015/0369522 A1
(43) Pub. Date: Dec. 24, 2015

(54) HEAT EXCHANGER

(71) Applicant: MAHLE INTERNATIONAL GMBH, Stuttgart (DE)

(72) Inventors: Jürgen Grünwald, Ludwigsburg (DE); Dirk Neumeister, Stuttgart (DE)

(73) Assignee: MAHLE INTERNATIONAL GMBH, Stuttgart (DE)

(21) Appl. No.: 14/655,408

(22) PCT Filed: Dec. 20, 2013
(86) PCT No.: PCT/EP2013/077783

§ 371 Date: Jun. 25, 2015

(30) Foreign Application Priority Data
Dec. 28, 2012 (DE) 10 2012 224 486.7

(51) Int. Cl. F25B 21/02; H01L 27/16; H01L 35/32

(52) U.S. Cl. CPC F25B 21/02; H01L 35/32; H01L 27/16

(57) ABSTRACT

The invention relates to a heat exchanger which has at least one first Peltier element. The Peltier element has a first semiconductor arrangement and at least one second semiconductor arrangement. Each semiconductor arrangement has a first semiconductor, a second semiconductor, and an electric contact. At least one semiconductor of each semiconductor arrangement is made of a p-doped semiconductor material, and at least one semiconductor of each semiconductor arrangement is made of an n-doped semiconductor material. One n-doped semiconductor and one p-doped semiconductor are electrically connected in series in an alternating manner within each semiconductor arrangement, and a voltage can be applied to said semiconductors via the electric contact. The invention is characterized in that the two semiconductor arrangements are electrically connected to each other in parallel.

### TECHNICAL AREA

The invention relates to a heat exchanger, which has at least one first Peltier element, wherein the Peltier element has a first semiconductor arrangement and at least one second semiconductor arrangement, wherein each semiconductor arrangement has a first semiconductor, a second semiconductor, and an electrical contact, wherein in each case at least one semiconductor of each semiconductor arrangement is manufactured from a p-doped semiconductor material and in each case at least one semiconductor is manufactured from an n-doped semiconductor material, wherein in each case an n-doped semiconductor and a p-doped semiconductor are alternately electrically connected in series inside the semiconductor arrangement and a voltage can be applied thereto via the electrical contact.

### PRIOR ART

In technical systems, in particular a motor vehicle, for example, various heating and cooling tasks are to be performed. A variety of various heat exchangers are used for this purpose, which can emit heat or absorb heat and dissipate it in accordance with the requirement.

These heat exchangers meet their limits when cooling below the ambient temperature is to be performed or heating is to be performed to a temperature level which cannot be achieved via the hottest heat source in the technical system, in the case of a motor vehicle the waste heat generated by the internal combustion engine. In this case, active cooling or active heating, respectively, must be performed.

Such active cooling can be performed, for example, by way of a thermal connection of the element to be cooled to an existing cooling circuit. The active heating can be performed, for example, by a heat pump, a fuel auxiliary heater, or an electrical heater. A variety of solutions are described in the prior art.

Furthermore, Peltier elements may also be used as heat exchangers for heating or cooling. This is conceivable in particular for the cooling and heating of electronic components in electric and hybrid vehicles.

The use of Peltier elements is particularly advantageous in this case, since no direct connection to coolant circuits must be performed for cooling individual elements. Furthermore, no moving parts are installed in Peltier elements, whereby the complexity of the structure is low.

For example, U.S. Pat. No. 4,314,008 discloses a battery system having active cooling of the battery cells. Peltier elements are used here for cooling the battery cells. A Peltier element consists in this case of a plurality of n-doped semiconductors and p-doped semiconductors, which are arranged between two insulation plates located in parallel to one another.

The individual n-doped semiconductors and p-doped semiconductors are arranged in this case in a series circuit. The concatenation of the n-doped semiconductors and p-doped semiconductors is performed alternately. Depending on the polarity of the applied voltage, heat is conveyed from one insulation plate to the opposing insulation plate through the n-doped semiconductors and p-doped semiconductors. The direction of the heat transport is reversed by reversing the polarity.

The solutions according to the prior art have the disadvantage that the individual n-doped semiconductors and the p-doped semiconductors of the Peltier element are connected in series. The entire current flow through the Peltier element is blocked by damage to a single n-doped semiconductor or p-doped semiconductor, whereby the Peltier element fails.

### DESCRIPTION OF THE INVENTION, PROBLEM, SOLUTION, ADVANTAGES

It is therefore the problem of the present invention to provide a heat exchanger, which is suitable for actively heating or cooling elements, wherein the heat exchanger has a high security against a failure and is simultaneously simple and cost-effective to produce.

The problem of the present invention is solved by a heat exchanger having the features of claim 1.

One exemplary embodiment of the invention relates to a heat exchanger, which has at least one first Peltier element, wherein the Peltier element has a first semiconductor arrangement and at least one second semiconductor arrangement, wherein each semiconductor arrangement has a first semiconductor, a second semiconductor, and an electrical contact, wherein in each case at least one semiconductor of each semiconductor arrangement is manufactured from a p-doped semiconductor material and in each case at least one semiconductor is manufactured from an n-doped semiconductor material, wherein in each case an n-doped semiconductor and a p-doped semiconductor are alternately electrically connected in series inside the semiconductor arrangement and a voltage can be applied thereto via the electrical contact, wherein the two semiconductor arrangements are electrically connected in parallel to one another.

The parallel circuit of the individual semiconductor arrangements in a Peltier element is advantageous in particular, since in the event of a defect of a single semiconductor, only the current flow through a semiconductor arrangement, in which the semiconductors are connected in series is interrupted, but not the current flow through the entire Peltier element. The Peltier element therefore remains functional in large parts in spite of the failure of a semiconductor and therefore a semiconductor arrangement.

In a Peltier element having semiconductors connected completely in series, a defect on only one semiconductor or one electrical bridge element results in the failure of the entire Peltier element. If multiple such Peltier elements are connected in series to one another, the entire circuit becomes nonfunctional.

In the case of the arrangement and interconnection according to the invention of the individual semiconductors, semiconductor arrangements, and Peltier elements, the security from failure is therefore substantially higher.

Furthermore, it can be particularly advantageous if the semiconductors are interconnected inside the semiconductor arrangements via electrically conductive bridge elements.

The electrically conductive bridge elements provide an electrical connection between the individual semiconductors of a semiconductor arrangement. In this case, the electrical bridge elements each connect an n-doped semiconductor and a p-doped semiconductor to one another.

A further preferred exemplary embodiment is characterized in that, upon application of a voltage, a first end region of the semiconductors heats up and an end region opposite to this end region cools down in each case, wherein the semiconductors are arranged such that the heating and cooling regions are each oriented in the same direction.

The alignment of the semiconductors such that the heating and cooling end regions are each oriented in a shared direction is particularly advantageous, since in this manner an oriented heat transport can take place along the individual semiconductors. A heat gradient therefore arises on the semiconductor arrangements or on the Peltier elements, respectively, when voltage is applied. This can be used to dissipate heat from an element to be cooled or to supply heat to an element to be heated.

It is also preferable if each Peltier element has a first insulation element and a second insulation element, wherein the semiconductors are arranged between the insulation elements in a plane and the semiconductors are in thermally conductive contact with the electrically conductive bridge elements and/or the insulation elements.

The insulation elements are primarily used for the electrical insulation of the semiconductors to the outside. This is necessary so as not to influence the current flow through the semiconductors or cause short circuits.

The insulation elements are advantageously to have a high thermal conductivity in this case, so as not to impair the heat transport, which is caused by the semiconductors.

In a particularly advantageous embodiment of the invention, it is additionally provided that a plurality of n-doped semiconductors and p-doped semiconductors are arranged alternately inside a semiconductor arrangement in each case.

A plurality of n-doped and p-doped semiconductors increases the heat transport capacity of the individual semiconductor arrangements and therefore the Peltier elements. To ensure the functionality of the heat exchanger, the semiconductors must be arranged such that current always alternately flows through one n-doped semiconductor and one p-doped semiconductor.

In an alternative embodiment of the invention, it can be provided that the heat exchanger has a plurality of Peltier elements, which are electrically connected in series to one another.

A plurality of Peltier elements is advantageous, since the heat transport capacity is increased as a whole in this way. In addition, the voltage level of the overall arrangement can be raised to an application-specific level (for example, 12 V or 48 V) via the series circuit of multiple Peltier elements. Each Peltier element operates at a lower voltage level per se in the case of semiconductor arrangements connected in parallel and, as a result, fewer leg pairs connected in series. However, the heating and cooling power is not noticeably changed in this way in relation to a Peltier element of identical materials, number of legs, and geometry of legs exclusively having a series circuit. For example, the very slight voltage drop and the current flow at an individual P/N leg pair remains substantially uninfluenced. Instead, the now higher total current strength of the Peltier element results as a product of the current of one semiconductor arrangement times the number of the parallel semiconductor arrangements. Furthermore, it is preferable if the insulation elements are embodied as flatly extended plate-like elements.

Flatly extended plate-like elements are particularly advantageous to attach elements to be cooled or heated thereon. The insulation elements can be used in this case as carriers for the elements to be cooled and/or to be heated.

In addition, it can be advantageous if semiconductor arrangements connected in parallel and semiconductor arrangements connected in series are arranged inside a Peltier element.

The security from failure of a Peltier element can be increased by way of a combination of semiconductor arrangements connected in series and semiconductor arrangements connected in parallel, and at the same time the reduction of the voltage level, which results due to the parallel circuit, can be kept as minimal as possible.

According to a particularly preferred refinement of the invention, it can be provided that it has a regulating unit, which measures overall resistances of individual semiconductor arrangements and/or overall resistances of individual Peltier elements and compares the measured ACTUAL values to stored SETPOINT values and, proceeding from the result, performs a regulation of the applied voltage to one or more semiconductor arrangements and/or to one or more Peltier elements.

A regulating unit is advantageous in particular if, as a result of a defect on one or more semiconductors, individual or multiple conduction pathways for the current, which flows through the heat exchanger, are blocked. This results in a change of the resistances of the semiconductors, the semiconductor arrangements, and the Peltier elements. Losses of the possible heat transport capacity can be compensated for via active regulation of the applied voltage.

Advantageous refinements of the present invention are described in the dependent claims and the following description of the figures.

### BRIEF DESCRIPTION OF THE DRAWINGS

The invention will be explained in detail hereafter on the basis of exemplary embodiments with reference to the drawings. In the drawings:

FIG. 1 shows a view of a semiconductor arrangement having a plurality of n-doped semiconductors and a plurality of p-doped semiconductors, which are connected to one another in series via line bridges,

FIG. 2 shows a top view of two Peltier elements, which are each constructed from a plurality of semiconductor arrangements, which extend in rows located parallel to one another along the Peltier element, wherein the semiconductor arrangements of each Peltier element are connected in parallel to one another, and the Peltier elements are connected in series to one another, and

FIG. 3 shows a top view of a heat exchanger, which consists of a plurality of Peltier elements, which are connected to one another in series.

### PREFERRED EMBODIMENT OF THE INVENTION

FIG. 1 shows a schematic view of a semiconductor arrangement 4. The semiconductor arrangement 4 essentially consists of bridge elements 1 and a plurality of p-doped semiconductors 2 and n-doped semiconductors 3.

The semiconductor arrangement 4 in FIG. 1 shows an arrangement which alternately provides a p-doped semiconductor 2 and an n-doped semiconductor 3. In each case a p-doped semiconductor 2 is connected via a bridge element to an n-doped semiconductor 3 located adjacent. The individual p-doped semiconductors 2 and n-doped semiconductors 3 are connected to one another in series.

As indicated in FIG. 1, the section shown of the semiconductor arrangement 4 is only a portion of a possibly substantially larger semiconductor arrangement. The semiconductor arrangement 4 can extend both to the left and also to the right still further beyond the region shown.

The semiconductor arrangement 4 can extend in a series, as shown in FIG. 1, which follows a straight line, for example. A semiconductor arrangement can just as well also contain multiple concatenations of p-doped semiconductors 2 and n-doped semiconductors 3 connected in series, however.

Via the application of a voltage to the bridge elements 1, a heat transport is triggered inside the semiconductor arrangement 4, which has the result that in each case one side of the p-doped semiconductors 2 and the n-doped semiconductors 3 heats up and the side opposite thereto cools down at the same time. The p-doped semiconductors 2 and n-doped semiconductors 3 are arranged in this case so that the cooling side and the heating side is oriented in each case in the same direction. For example, in the semiconductor arrangement 4 shown in FIG. 1, the upper side of the p-doped semiconductors 2 and n-doped semiconductors 3 heats up, while the lower side cools down. The upper side is cooled down and the lower side is heated up accordingly by way of a change of the polarity of the flowing current.

To ensure good heat transport, it is advantageous if the bridge elements 1 have a high thermal conductivity.

In an alternative embodiment, the semiconductor arrangement 4 can be arranged between two insulation elements. The insulation elements are used for the electrical insulation of the semiconductor arrangement to the outside and can simultaneously be used for attaching elements to be cooled or to be heated. The insulation elements are advantageously attached in this case so that the bridge elements are in thermally conductive contact with the insulation elements. The insulation elements preferably have a high thermal conductivity, so that a heat transport can take place through the insulation elements in as unobstructed a manner as possible.

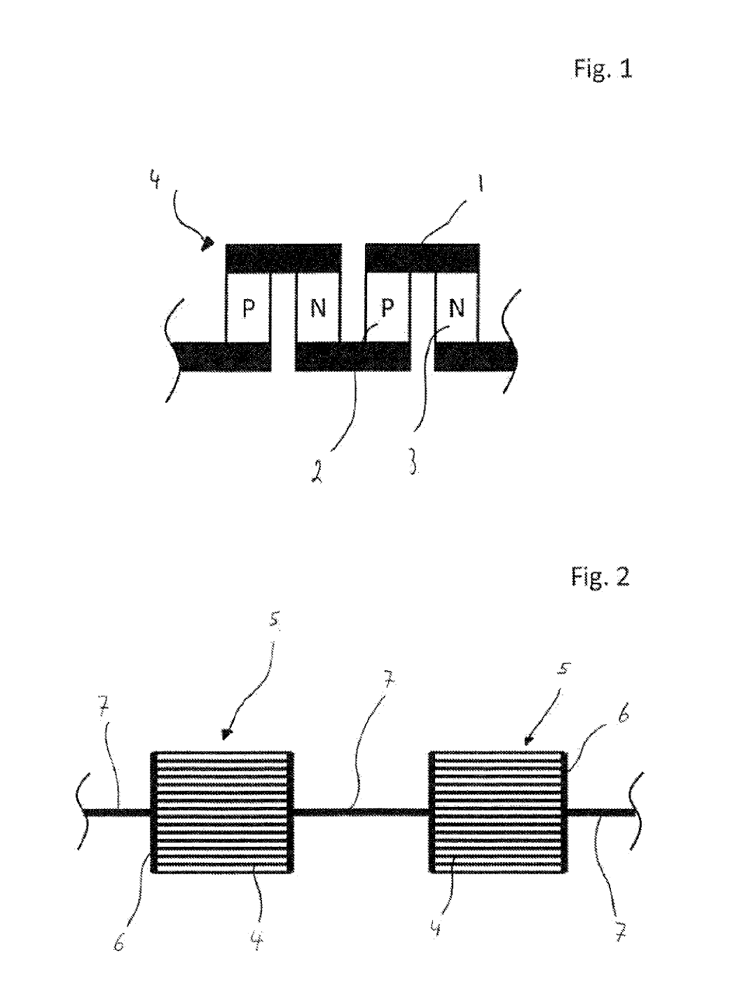

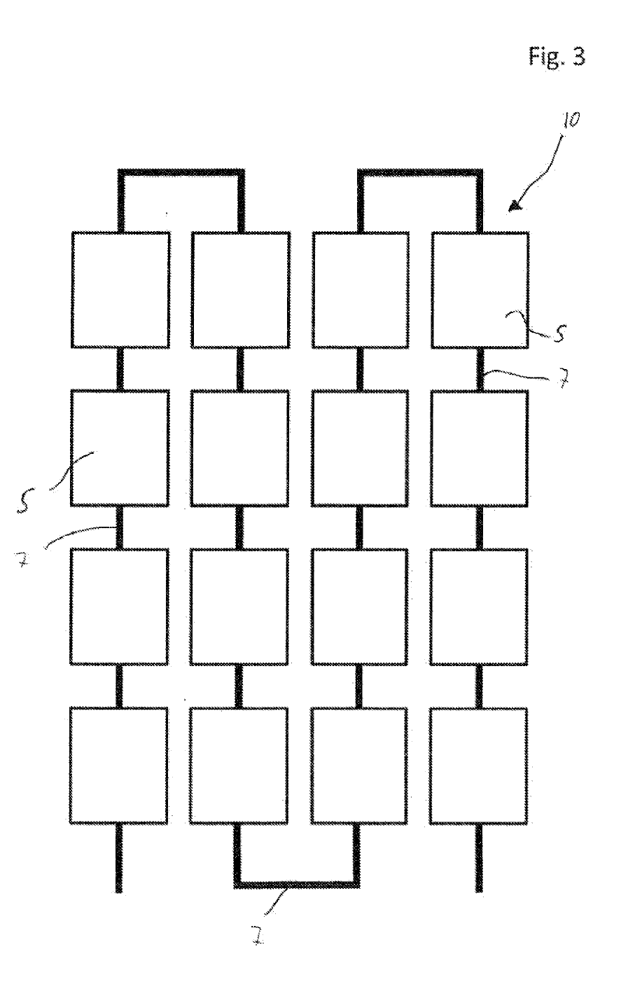

FIG. 2 shows two Peltier elements 5, which each consist of a plurality of semiconductor arrangements 4. The individual Peltier elements 5 are connected in series to one another via the current conductors 7. Series of semiconductor arrangements 4 are provided inside the Peltier elements 5, which extend in parallel to one another along the Peltier element. In differing embodiments, the semiconductor arrangements can also be arranged in a differing arrangement inside the Peltier element.

The semiconductor arrangements 4 can each consist in the simplest case of a series of p-doped semiconductors 2 and n-doped semiconductors 3 connected one after another, which are connected to one another via bridge elements. It is also possible to combine multiple p-doped semiconductors 2 and n-doped semiconductors 3 adjacent to one another to form a semiconductor arrangement 4. The semiconductor arrangements 4 form a closed unit per se in each case inside the Peltier element 5 in this case. The individual semiconductor arrangements 4 are connected to one another in parallel inside the Peltier element 5. The distribution of the current to the individual semiconductor arrangements 4 connected in parallel is performed via the current conductor 6.

The parallel arrangement of the semiconductor arrangements 4 inside a Peltier element 5 is advantageous in particular since the probability of failure of an entire Peltier element 5 is thus significantly reduced. If a single p-doped semiconductor element 2, an n-doped semiconductor element 3, or a single bridge element 1 is damaged, only the current flow inside one semiconductor arrangement 4 is interrupted. Due to the parallel connection of multiple semiconductor arrangements 4, the current flow through the Peltier element 5 is still maintained overall. The Peltier element 5 only loses the heat transport power of one semiconductor arrangement 4 in this case.

The Peltier element 5 is therefore substantially more robust and failsafe than a Peltier element which is constructed solely from a series circuit of p-doped semiconductors and n-doped semiconductors.

FIG. 2 only shows a portion of a larger set of Peltier elements 5. A single Peltier element 5 or a plurality of Peltier elements 5 can represent a heat exchanger in this case, which can be used for heating or cooling elements, for example, in a vehicle.

FIG. 3 shows a heat exchanger 10, which consists of an arrangement of 16 Peltier elements 5. The construction of the individual Peltier elements 5 corresponds to the construction described in FIG. 2 of semiconductor arrangements 4 connected to one another in parallel inside the Peltier element 5, and also a series circuit of the individual Peltier elements 5 with one another. The Peltier elements 5 are connected to one another in series via the current conductor 7.

The arrangement of 16 Peltier elements 5 in four rows in each case as shown in FIG. 3 is an example. A number of Peltier elements differing from this number can be provided at any time. An arrangement differing from that in FIG. 3 can also be provided. As long as the individual Peltier elements 5 are connected to one another in series and the internal structure of the Peltier elements 5 corresponds to the structure of FIG. 2, a nearly arbitrary design possibility is provided for the heat exchanger 10.

In alternative embodiments, it can also be provided that multiple Peltier elements are connected to one another in parallel and an arrangement of multiple Peltier elements connected in parallel is connected in series to a further arrangement of individual or multiple Peltier elements. The Peltier elements 5 can either each have insulation elements per se in this case, which terminate the semiconductor arrangement 4 on the top or bottom, or it can also be provided that a plurality of Peltier elements is arranged between a shared upper and a shared lower insulation element.

The illustrated embodiments each only represent examples and serve for better understanding of the structure of the heat exchanger 10 or the Peltier elements 5. They do not have restrictive character.

1. A heat exchanger, which has at least one first Peltier element, wherein the Peltier element has a first semiconductor arrangement and at least one second semiconductor arrangement, wherein each semiconductor arrangement has a first semiconductor, a second semiconductor, and an electrical contact, wherein in each case at least one semiconductor of each semiconductor arrangement is manufactured from a p-doped semiconductor material and in each case at least one semiconductor is manufactured from an n-doped semiconductor material, wherein in each case an n-doped semiconductor and a p-doped semiconductor are alternately electrically connected in series inside the semiconductor arrangement and a voltage can be applied thereto via the electrical contact, wherein the two semiconductor arrangements are electrically connected in parallel to one another.

2. The heat exchanger as claimed in claim 1, wherein the semiconductors are interconnected inside the semiconductor arrangements via electrically conductive bridge elements.

3. The heat exchanger as claimed in claim 1, wherein, upon application of a voltage, a first end region of the semiconductors heats up and an end region opposite to this end region cools down in each case, wherein the semiconductors are arranged such that the heating and cooling regions are each oriented in the same direction.

4. The heat exchanger as claimed in claim 1, wherein each Peltier element has a first insulation element and a second insulation element, wherein the semiconductors are arranged between the insulation elements in a plane and the semiconductors are in thermally conductive contact with the electrically conductive bridge elements and/or the insulation elements.

5. The heat exchanger as claimed in claim 1, wherein a plurality of n-doped semiconductors and p-doped semiconductors are arranged alternately inside a semiconductor arrangement in each case.

6. The heat exchanger as claimed in claim 1, wherein the heat exchanger has a plurality of Peltier elements, which are electrically connected in series to one another.

7. The heat exchanger as claimed in claim 1, wherein the insulation elements are embodied as flatly extended plate-like elements.

8. The heat exchanger as claimed in claim 1, wherein semiconductor arrangements connected in parallel and semiconductor arrangements connected in series are arranged inside a Peltier element.

9. The heat exchanger as claimed in claim 1, wherein it has a regulating unit, which measures overall resistances of individual semiconductor arrangements and/or overall resistances of individual Peltier elements and compares the measured ACTUAL values to stored SETPOINT values and, proceeding from the result, performs a regulation of the applied voltage to one or more semiconductor arrangements and/or to one or more Peltier elements.
